(19) United States
(12) Patent Application Publication
(10) Pub. No.: US 2026/0190496 A1
(43) Pub. Date: Jul. 2, 2026

(54) METHOD OF FORMING A SEMICONDUCTOR DEVICE

(71) Applicant: TAIWAN SEMICONDUCTOR MANUFACTURING COMPANY LTD., HSINCHU (TW)

(72) Inventors: WEI-CHENG TZENG, TAIPEI (TW); CHUN-YEN LIN, HSINCHU CITY (TW); WEI-CHENG LIN, TAICHUNG CITY (TW); JIANN-TYNG TZENG, HSINCHU (TW)

(21) Appl. No.: 19/001,612

(22) Filed: Dec. 26, 2024

(51) Int. Cl. H10D 89/10; H01L 21/28; H01L 23/528; H10D 84/85

(52) U.S. Cl. CPC H10D 89/10; H10D 64/01326; H10D 84/85; H10W 20/43

(57) ABSTRACT

The present disclosure provides a method of forming a semiconductor device. The method comprises: generating, by a processor, a circuit layout of the standard cell, wherein the generating of the circuit layout comprises: generating a first gate layout pattern corresponding to fabricating a first gate structure of the standard cell; determining a first pin at the first gate layout pattern; and determining a first pin solution based on the first pin; and manufacturing the standard cell based on the circuit layout, the standard cell having the first gate structure.

### TECHNICAL FIELD

The disclosure relates to a method of forming a semiconductor device (e.g., a standard cell).

### BACKGROUND

A circuit layout includes one or more standard cells which correspond to active devices having a specific functionality. Cells for active devices which are routinely repeated are often included in a cell library. These cells are called standard cells in some instances. Cells include pins, which are used to convey signals into and out of the cell. At least one pin of a cell is connected to a pin of at least one other cell in order to transfer signals between the various cells. Routing lines are provided to interconnect the pins of various cells to facilitate signal transfer between different cells to provide a desired functionality for the circuit layout.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a three dimensional view of a semiconductor device in accordance with some embodiments of the present disclosure.

FIG. 2A is a schematic view of a layout of a frontside of a semiconductor device in accordance with some embodiments of the present disclosure.

FIG. 2B is a schematic view of a layout of a backside of a semiconductor device in accordance with some embodiments of the present disclosure.

FIG. 3 is a flowchart of a method of manufacturing a standard cell, in accordance with some embodiments.

FIG. 4 is a flowchart of a method for generating a simulated standard cell design layout, in accordance with some embodiments of the present disclosure.

FIG. 5 is a flow chart of a method of generating a circuit layout of a standard cell in accordance with some embodiments of the present disclosure.

FIG. 6A is a flow chart of a method of generating a circuit layout of a standard cell in accordance with some embodiments of the present disclosure.

FIG. 6B is a flow chart of a method of generating a circuit layout of a standard cell in accordance with some embodiments of the present disclosure.

FIG. 7 is a block diagram of generating a circuit layout of a standard cell in accordance with some embodiments of the present disclosure.

FIG. 8 is a flow chart of a method of generating a circuit layout of a standard cell in accordance with some embodiments of the present disclosure.

FIG. 9A is a block diagram of a layout of a NAND device in accordance with some embodiments of the present disclosure.

FIG. 9B is a block diagram of a layout of a NAND device in accordance with some embodiments of the present disclosure.

FIG. 9C is a block diagram of a layout of a NAND device in accordance with some embodiments of the present disclosure.

FIG. 10 is a block diagram of a layout of a standard cell (e.g., an inverter) 705 in accordance with some embodiments of the present disclosure.

FIG. 11 is a diagram illustrating an electronic design automation system, in accordance with some embodiments of the present disclosure.

FIG. 12 is a block diagram of an IC layout diagram generation system, in accordance with some embodiments.

FIG. 13 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are as follows to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed below using specific language. It will nevertheless be understood that the embodiments and examples are not intended to be limiting. Any alterations and modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, the following description should be understood to represent examples only, and are not intended to suggest that one or more steps or features is required.

In addition, the present disclosure may repeat reference numerals and/or letters in the various examples. This repetition is for the purpose of simplicity and clarity and does not in itself dictate a relationship between the various embodiments and/or configurations discussed.

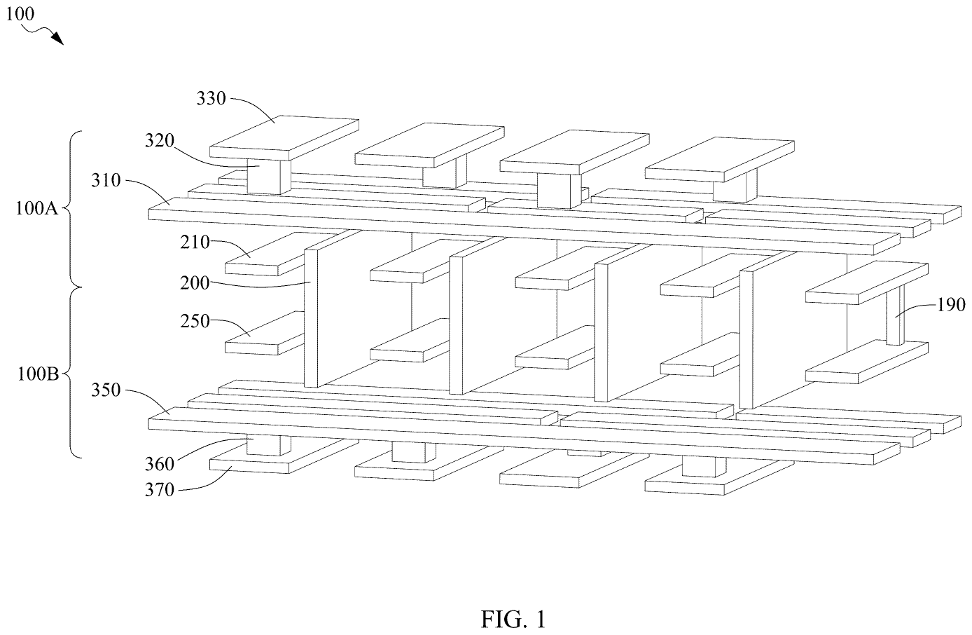

FIG. 1 is a three dimensional view of a standard cell 100 in accordance with some embodiments of the present disclosure. The standard cell 100 may include a plurality of vertically arranged complementary FETs (CFETs). The standard cell 100 includes a gate structure 200, a first metal over diffusion (MD) region 210, a second MD region 250, and an interconnection structure 190. The gate structure 200, the first metal over diffusion (MD) region 210, the second metal over diffusion (MD) region 250, and the interconnection structure 190 may collectively form the plurality of vertically arranged CFETs. The interconnection structure 190 may include through-silicon vias (TSVs) connecting the first MD region 210 and the second MD region 250. In some embodiments, material of the gate structure 200 may include polysilicon, carbon, Germanium, metal, or III-V semiconductors.

The standard cell 100 may include a first frontside conductive layer 310, a plurality of frontside vias 320, and a second frontside conductive layer 330. The first frontside conductive layer 310 may be referred to as a zero metal layer (M0). The vias 320 may be referred to as zero vias (VIA0). The second frontside conductive layer 330 may be referred to as a first metal layer (M1). The first frontside conductive layer 310 may be electrically connected to the gate structure 200, and the first MD region 210. The first frontside conductive layer 310 may be electrically connected to the second frontside conductive layer 330 through the frontside vias 320.

The standard cell 100 may include a first backside conductive layer 350, a plurality of backside vias 360, and a second backside conductive layer 370. The first backside conductive layer 350 may be referred to as a backside zero metal layer (BM0). The vias 360 may be referred to as backside zero vias (BVIA0). The second backside conductive layer 370 may be referred to as a backside first metal layer (BM1). The first backside conductive layer 350 may be electrically connected to the gate structure 200, and the second MD region 250. The first backside conductive layer 350 may be electrically connected to the second backside conductive layer 370 through the backside vias 360.

The standard cell 100 may include a frontside (or a frontside region) 100A and a backside (or a backside region) 100B. The frontside 100A may include the gate structure 200, the first MD region 210, the first frontside conductive layer 310, the plurality of frontside vias 320, and the second frontside conductive layer 330. The backside 100B may include the gate structure 200, the second MD region 250, the first backside conductive layer 350, the plurality of backside vias 360, and the second backside conductive layer 370.

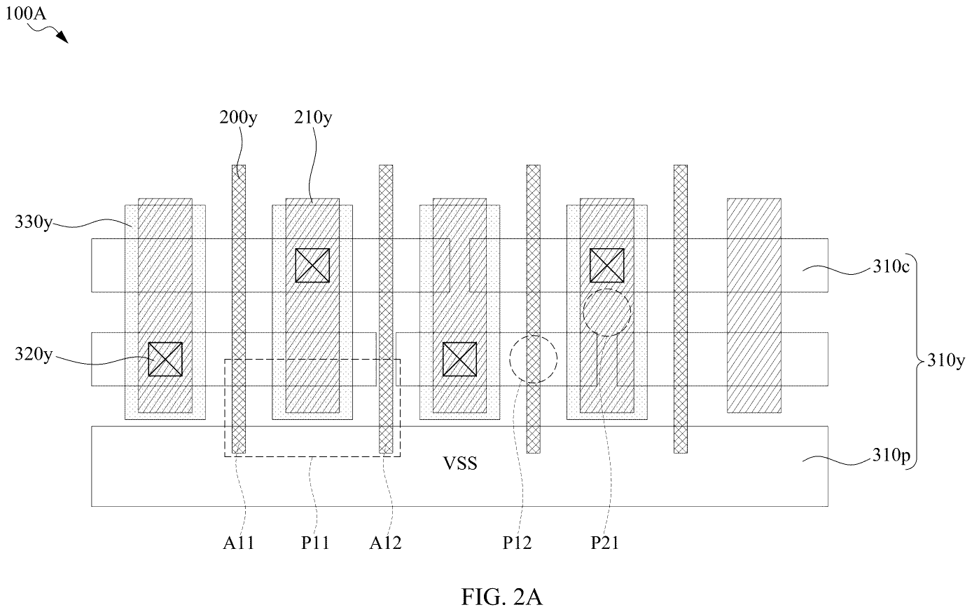

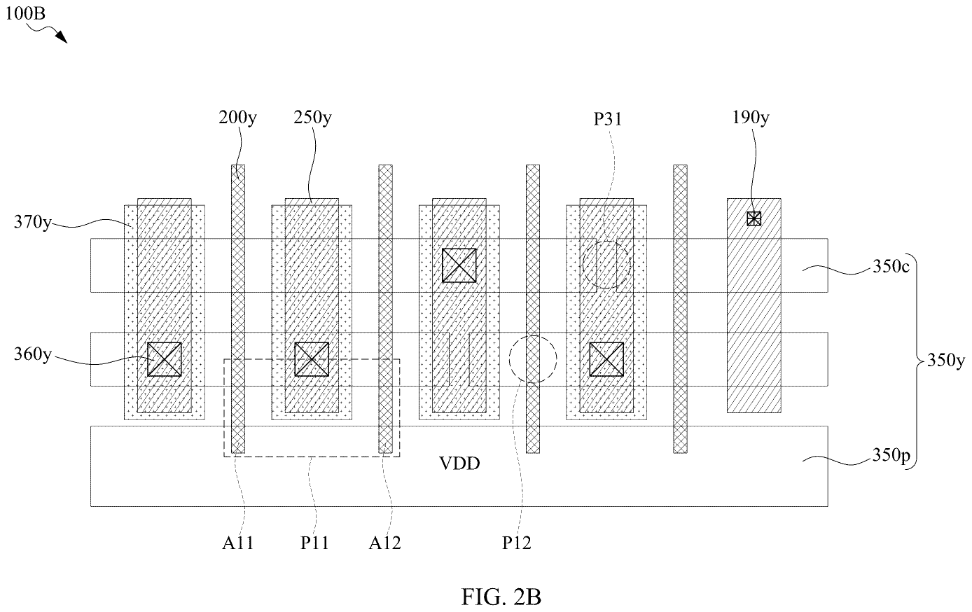

FIG. 2A is a schematic view of a layout of a frontside 100A of a standard cell in accordance with some embodiments of the present disclosure. As shown in FIG. 2A, a gate layout pattern (or POLY layout pattern) 200y corresponds to the gate structure 200 of the standard cell 100. A first MD layout pattern 210y corresponds to the first MD region 210 of the standard cell 100. A first frontside conductive feature layout pattern 310y corresponds to the first frontside conductive layer 310 of the standard cell 100.

The first frontside conductive feature layout pattern 310y may include a first part 310c configured to transmit data signals to and from the vertically arranged complementary FETs. The frontside conductive feature layout pattern 310y may include a second part 310p configured to transmit power signals (e.g., VSS) to and from the vertically arranged complementary FETs (CFET). The frontside conductive feature layout pattern 310y may have a part for the internal routing of a cell and a part for the intra-cell routing among the cells.

Referring to FIG. 2A, a via layout pattern 320y corresponds to the frontside vias 320 of the standard cell 100. A second frontside conductive feature layout pattern 330y corresponds to the second frontside conductive layer 330 of the standard cell 100. The overlapping of the first frontside conductive feature layout pattern 310y, the via layout pattern 320y, and second frontside conductive feature layout pattern 330y may indicate the electrical connection therebetween.

FIG. 2B is a schematic view of a layout of a backside 100B of a standard cell in accordance with some embodiments of the present disclosure. As shown in FIG. 2B, a second MD layout pattern 250y corresponds to the second MD region 250 of the standard cell 100.

FIG. 2B may also show an interconnection layout pattern 190y for the interconnection structure 190 of the standard cell 100. A first backside conductive feature layout pattern 350y corresponds to the first backside conductive layer 350 of the standard cell 100. A backside via layout pattern 360y corresponds to the backside vias 360 of the standard cell 100. A second backside conductive feature layout pattern 370y corresponds to the second backside conductive layer 370 of the standard cell 100. The overlapping of the first backside conductive feature layout pattern 350y, the backside via layout pattern 360y, and second backside conductive feature layout pattern 370y may indicate the electrical connection therebetween.

Referring to FIG. 2B, the first backside conductive feature layout pattern 350y may include a first part 350c configured to transmit data signals to and from the vertically arranged CFETs. The first backside conductive feature layout pattern 350y may include a second part 350p configured to transmit power signals (e.g., VSS) to and from the vertically arranged CFETs. The first backside conductive feature layout pattern 350y may have a part for the internal routing of a cell and a part for the intra-cell routing among the cells.

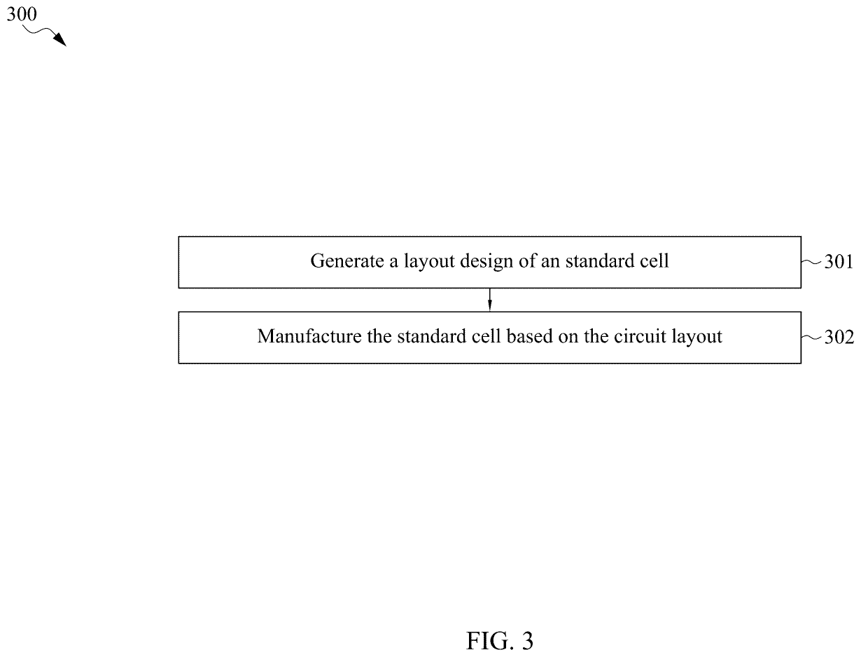

FIG. 3 is a flowchart of a method 300 of manufacturing a standard cell, in accordance with some embodiments. It is understood that additional operations may be performed before, during, and/or after the method 300 depicted in FIG. 3, and that some other processes may only be briefly described herein. In some embodiments, the method 300 is usable to form standard cells, such as standard cell 100 (FIG. 1).

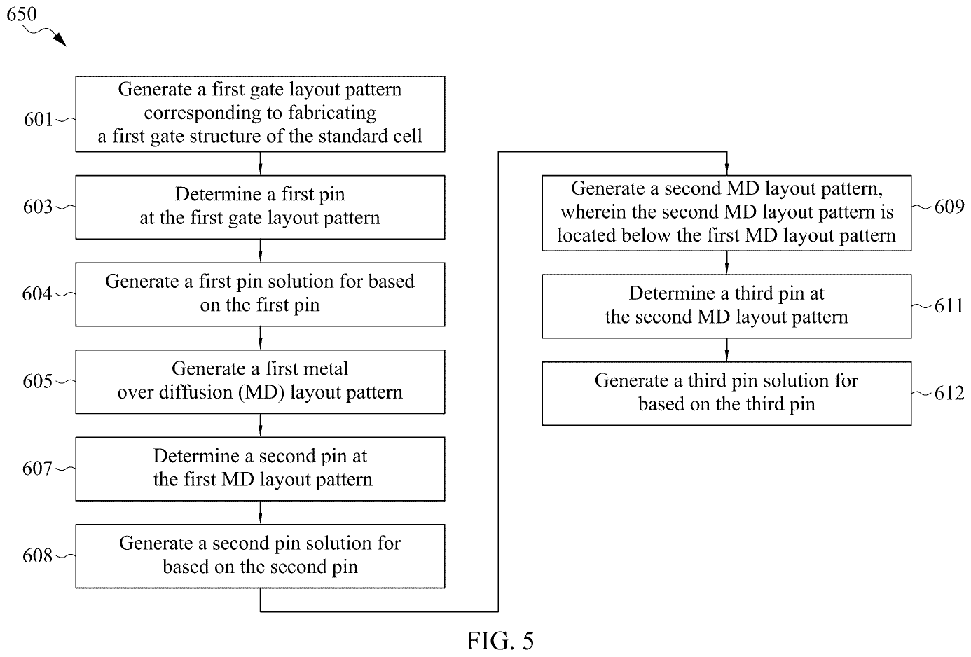

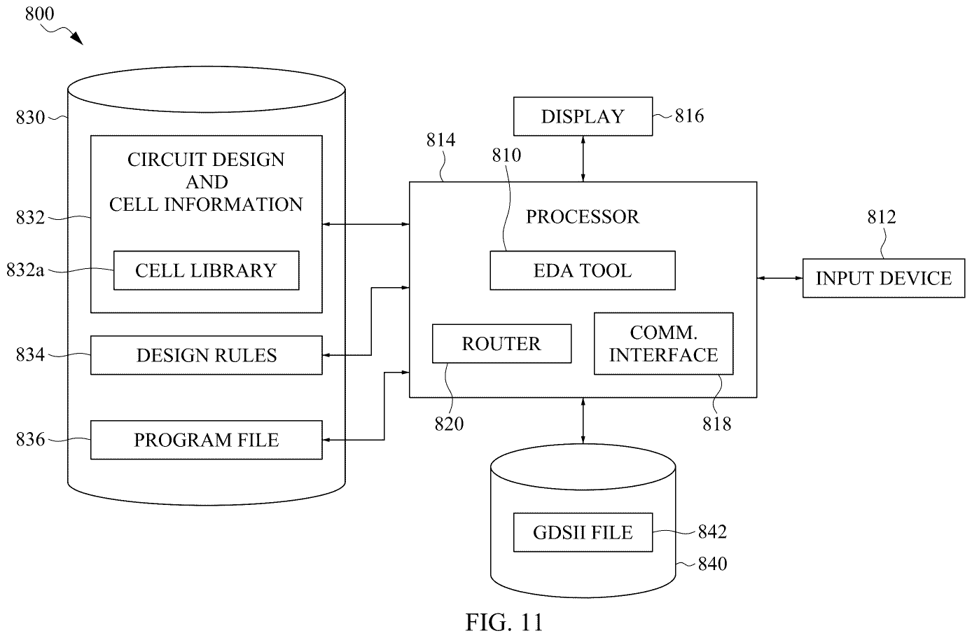

In operation 301 of method 300, a circuit layout of a standard cell is generated. In some embodiments, the circuit layout of method 300 includes one or more circuit layouts, such as one or more circuit layouts of a standard cell, such as standard cell 100 (FIG. 1). In some embodiments, operation 301 of method 300 is performed by a processing device (e.g., processor 814 of FIG. 11) configured to execute instructions for generating a circuit layout, which may be a tape-out file for manufacturing the standard cell. The tape-out file may be stored in a graphic database system (GDSII) file format. The details of the operation 301 will be discussed in the flow charts of FIGS. 5, 6A, 6B, and 8.

Method 300 continues with operation 302, wherein the standard cell (e.g., standard cell 100) is manufactured based on one or more circuit layouts.

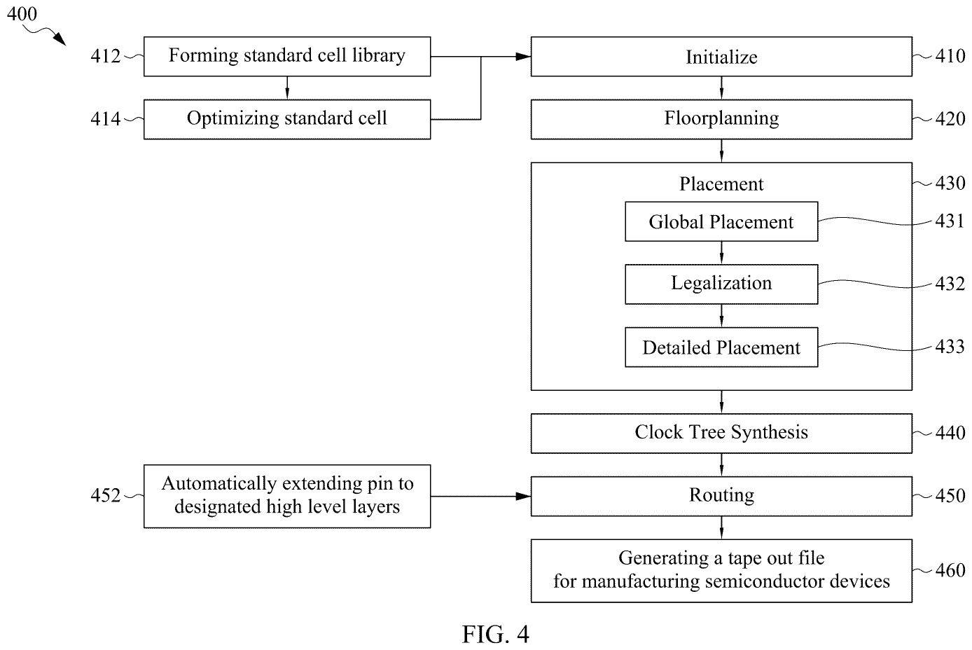

FIG. 4 is a flowchart 400 showing a method for generating a simulated standard cell design layout, in accordance with some embodiments of the present disclosure. In some embodiments, this method may correspond to an automatic placement and routing (APR) process. In some embodiments, the APR process of the present disclosure may be applied to any suitable simulated standard cell design layout.

The APR process shown in FIG. 4 may begin in operation 410, initializing a pre-placement of a simulated standard cell design layout. For example, the pre-placement simulation may be generated according to design data corresponding to a standard cell layout stored in a data storage device. In some embodiments, the pre-placement simulation may be executed on the design, e.g., by an EDA tool, to determine whether the design meets a predetermined specification. If the design does not meet the predetermined specification, the semiconductor device needs to be redesigned. In some embodiments, a SPICE simulation is performed on the SPICE netlist. Other simulation tools can be employed, in place of or in addition to the SPICE simulation, in other embodiments.

In operation 420, floor planning for the standard cell is performed, for example, by a system 800 of FIG. 11. In some embodiments, the floor planning includes dividing a circuit into functional blocks, which are portions of the circuit, and identifying the layout for these functional blocks.

In operation 430, an automated placement tool may create a transistor level design by placing cells from a cell library to form the various logic and functional blocks according to the IC design. In some embodiments, the system 800 performs placement for the standard cell. In some embodiments, operation 430 includes determining the placement for the electronic components, circuitry, and logic elements. For example, the placement of the transistors, resistors, inductors, logic gates, and other elements of the standard cell can be selected in operation 430.

In some embodiments, operation 430 can include sub-operations such as global placement 431, legalization 432, and detailed placement 433.

Global placement 431 is a rough placement of the simulated standard cell design layout. In some embodiments, global placement 431 includes distributing the cells in the simulated standard cell design layout with overlaps. During global placement 431, a placement tool can be used to generate an automatic placement of the cells with approximately regular cell densities while minimizing wire length. Global placement 431 can utilize partitioning-based techniques, simulated annealing-based techniques, analytical placement techniques, or any combination thereof. In some embodiments, the simulated standard cell design layout includes cells arranged in rows. In one embodiment, the cell rows in the simulated standard cell design layout can be of the same height. In another embodiment, the cell rows in the simulated standard cell design layout can be of different heights.

After global placement 431, cells may still overlap and be misaligned with the rows. To remedy the overlap and misalignment, legalization 432 includes removing any remaining overlaps between the cells and aligning all the cells in the simulated standard cell design layout. That is, legalization 432 legalizes global placement 431. In other words, legalization 432 places cells at legal placement sites and removes overlaps. Therefore, legalization 432 removes white spaces in the simulated standard cell design layout.

Detailed placement 433 further improves wire length (or other problems) by locally rearranging the cells while maintaining legality. That is, the detailed placement 433 provides a final placement based on the legality and wire length.

In operation 440, Clock Tree Synthesis (CTS) may be performed after the placement of cells. In some embodiments, a CTS tool synthesizes a clock tree for the entire simulated standard cell design layout. As it does so, the CTS tool establishes only an approximate position for each buffer forming the clock tree and only approximates the routing of signal paths that will link the buffers to one another and to synchronization, so that it can make reasonably accurate estimates of signal path delays through the clock tree.

In operation 450, an automatic routing tool then determines the connections needed between the devices in the cells, such as MOS transistors. Multiple transistors are coupled together to form functional blocks, such as adders, multiplexers, registers, and the like, in the routing step. Routing comprises the placement of signal net wires on a metal layer within placed cells to carry non-power signals between different functional blocks. In some embodiments, signal net wires are routed on the same metal level as one of the vertically adjacent metal layers in the multilevel power rails.

Once the routing is determined, automated layout tools are used to map the cells and the interconnections from the router onto a semiconductor device using the process rules and the design rules, as provided. All of these software tools are available commercially for purchase. Cell libraries that are parameterized for certain semiconductor wafer manufacturing facilities are also available.

In operation 460, a tape out data file corresponding to a standard cell layout of a semiconductor device may be generated. In some embodiments, the standard cell design layouts can include FinFET devices and/or other planar or more complex structural semiconductor manufacturing processes.

The APR process in FIG. 4 may include an operation 412, forming a standard cell library. The operation 412 may be part of the operation 410. The details of the operation 412 will be discussed in FIG. 5. The standard cell library includes a plurality of standard cells, such as an inverter, NAND, NOR, flip-flop circuit, latch-up circuit, etc. The standard cells are formed by a plurality of vertically arranged CFETs. Due to the design of the standard cells with CFETs, they can be interconnected with other cells using frontside and/or backside conductive patterns. The number of the cell offerings for each type of the standard cells will be significantly increased, and will occupy the operation capacity and storage capacity of a processor (e.g., the processor 814 in FIG. 11).

The present disclosure includes forming a standard cell with modified pin(s). The modified pin(s) of the standard cell are at the gate level (or poly (PO) level) and the MD level for reducing the number of cell offerings for the standard cell library. When the modified pin(s) are set at the PO level and the MD level, the pin accesses thereof are fixed based on the layout (e.g., PO layout and MD layout) of the standard cell. Thus, the numbers of the pin accesses can be reduced. The number of cell offerings with the modified pins can be reduced to one.

The pin solution of the modified pins can be constrained by a reference pin solution which is only on frontside conductive layers or backside conductive layers. The reference pin solution prevent a relatively inadequate power consumption (or speed, area) performance of a target pin solution. Furthermore, a frequently used standard cell may be optimized to improve the power consumption (or speed, area) performance. The frequently used standard cell may be used to increase the numbers of the cell offerings.

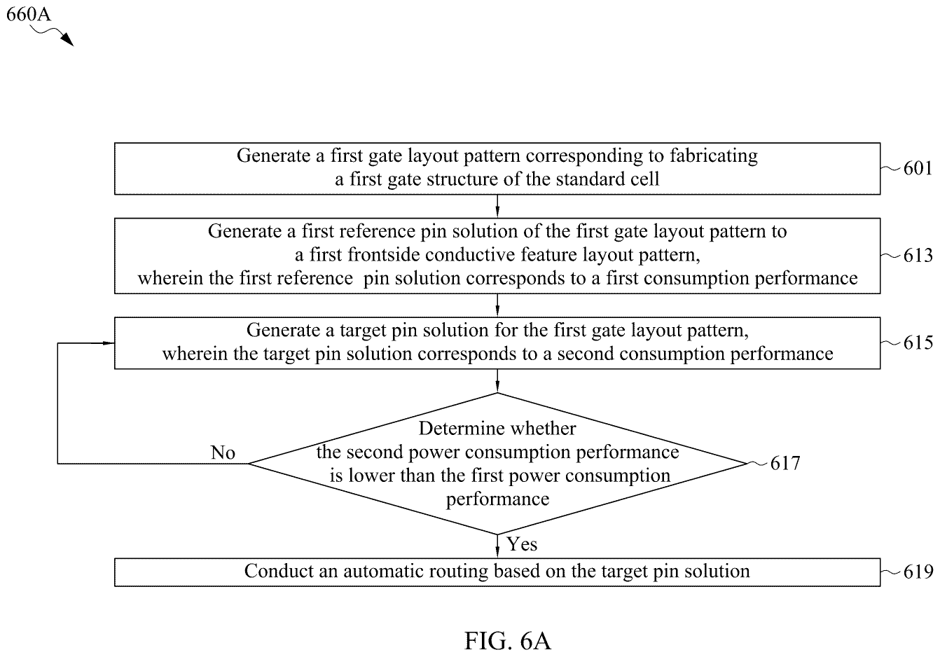

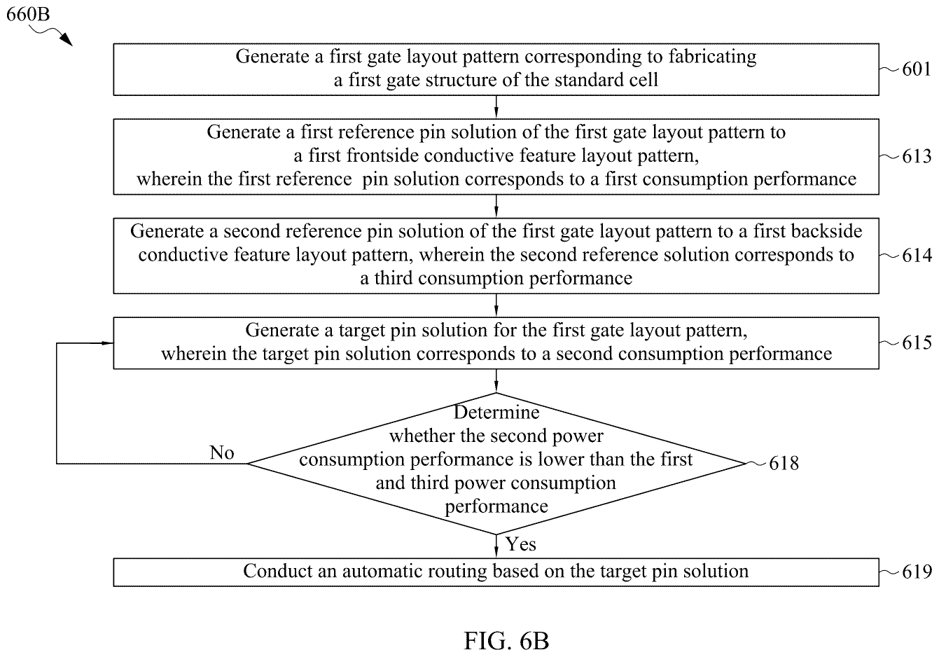

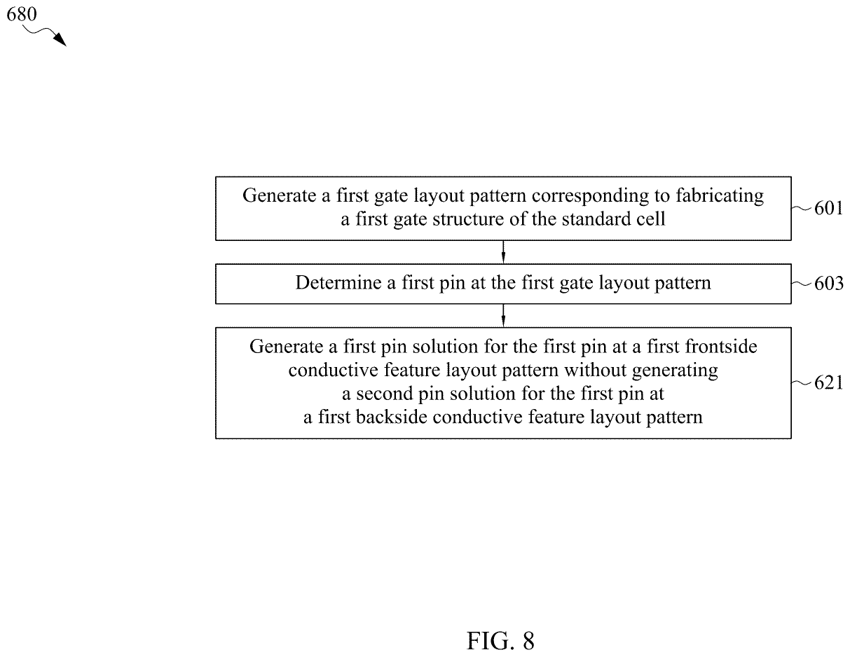

The APR process in FIG. 4 may include an operation 414, optimizing at least one standard cell. The operation 412 may be part of the operation 410. The details of the operation 412 will be discussed in FIGS. 6A, 6B, and 8. The operation 414 can include optimizing frequently used standard cells to improve the power, area, or speed performance.

In operation 410, the method 650 of FIG. 5, the method 660A of FIG. 6A, the method 660B of FIG. 6B, and the method 680 of FIG. 8 can be collectively performed.

The APR process in FIG. 4 may include an operation 452, automatically extending pin to designated high level layers. The operation 452 may be part of the operation 450. The operation 452 may automatically extend the modified pins (at the PO and MD levels) to designated high level layers (e.g., M0, BM0, M1, BM1, etc.). The operation 452 may further include connecting the standard cell to another cell through the designated high level layers.

FIG. 5 is a flow chart of a method 650 of generating a circuit layout of a standard cell in accordance with some embodiments of the present disclosure.

The method 650 of FIG. 5 may begin in operation 601, generating a first gate layout pattern (e.g., the gate layout pattern 200y) corresponding to fabricating a first gate structure (e.g., the gate structure 200) of a standard cell. In some embodiments, the first gate structure is a part of a vertically arranged CFET.

In operation 603, the method 650 includes determining a first pin at the first gate layout pattern. Referring back to FIGS. 2A and 2B, a pin P11 is on the gate layout pattern 200y. The pin P11 may have a circular shape or rectangular shape. The pin P11 is at a first level. The first level may be the gate level (or PO level) and the MD level. In some embodiments, a further pin P12 is on the gate layout pattern 200y. The pin P11 and the pin P12 are for different signals (e.g., signal A and signal B, respectively). The pin P11 may not overlap the pin P12. The pin P11 may be defined by a non-physical layout layer (e.g., “pin text”) in a layout software. The non-physical layout layer may be defined as the PO level pin for the signal A. The intersection between the pin P11 and the gate layout pattern 200y may determine pin accesses A11 and A12. That is, the signal A may have a plurality of pin access. The signal A may be transmitted to the pin accesses A11 and/or A12. In some embodiments, the signal B (e.g., the pin P12) may have a single pin access. The pin accesses of the pin P11 and the pin P12 may be determined based on the type of the standard cell. In some embodiments, the accesses of the pin P11 and the pin P12 may be fixed. The determining of the first pin at the first gate layout pattern reduces the number of cell offerings of the circuit layout.

In some embodiments, the first level (e.g., PO level and MD level) is different from a second level (e.g., zero metal (M0) level), at which the first frontside conductive feature layout pattern 310y is located. In some embodiments, the second level farther from a substrate than the first level is described as being “above” the first level. The first level is different from a third level (e.g., backside zero metal (BM0) level), at which the first backside conductive feature layout pattern 350y is located. In some embodiments, the third level farther from a substrate than the first level is described as being “above” the first level.

In operation 604, the method 650 includes generating a pin solution based on the pin P11 (e.g., at/on the PO level). A pin solution refer to a possible arrangement of the input pins and output pins that allows signals to be transmitted to a specified layer (e.g., PO level, metal layer M1, M2, . . . etc). For example, if there are three input pins A, B, and C and one output pin O, there can be various arrangements for these pins on the metal layer M1. The pin solution may have the information of the position/location of the pin P11, as well as the positions/locations of other pins at the same layer. In some embodiments, the position/location of the pin P11 indicates which level (e.g., PO level) it is designated to. The pin solution may have the information of the input pin of a standard cell. The pin solution may have the information of the output pin of a standard cell. The pin solution may have the information of the pin accesses A11 and A12 of the pin P11.

In some embodiments, the operation 604 may further include generating a pin solution based on the pin P12. The pin solution may have the information of the position/location of the pin P12, as well as the positions/locations of other pins. In some embodiments, the position/location of the pin P12 indicates which level (e.g., PO level) it is designated to. The pin solution may have the information of the input pin of a standard cell. The pin solution may have the information of the pin accesses of the pin P12.

In operation 605, the method 650 includes generating a first metal over a diffusion (MD) layout pattern (e.g., the first MD layout pattern 210y). In some embodiments, the first gate layout pattern 200y and the first MD layout pattern 210y collectively determine a set of n-type transistors.

In operation 607, the method 650 includes determining a second pin at the first MD layout pattern (e.g., the first MD layout pattern 210y). Referring back to FIG. 2A, a pin P21 is on the first MD layout pattern 210y. The pin P21 may have a circular shape or rectangular shape. The pin P21 is at the first level. The pin P21 may be defined by a non-physical layout layer in a layout software. The non-physical layout layer may be defined as the MD level pin for the signal OUT. The intersection between the pin P21 and the first MD layout pattern 210y may determine a pin access. The signal OUT may be transmitted from the pin access. The pin access of the pin P21 may be determined based on the type of the standard cell. In some embodiments, the pin access of the pin P21 may be fixed. The pin access of the pin P21 may not overlap the pin accesses A11 and A12 of the pin P11. The determining of the second pin (e.g. P21) at the first MD layout pattern 210y reduces the number of cell offerings of the circuit layout.

In operation 608, the method 650 includes generating a pin solution for the pin P21. The pin solution may have the information of the position/location of the pin P21. In some embodiments, the position/location of the pin P21 indicates which level (e.g., MD level) it is designated to. The pin solution may have the information of the output pin of a standard cell. The pin solution may have the information of the pin access of the pin P21.

In operation 609, the method 650 includes generating a second MD layout pattern (e.g., the second MD layout pattern 250y), wherein the second MD layout pattern is located below the first MD layout pattern. In some embodiments, the first gate layout pattern 210y and the second MD layout pattern 250y collectively determine a set of p-type transistors.

In operation 611, the method 650 includes determining a third pin at the second MD layout pattern. Referring back to FIG. 2B, a pin P31 is on the second MD layout pattern 250y. The pin P31 may have a circular shape or rectangular shape. The pin P31 is at the first level. The first pin P11, the second pin P21, and the third pin P31 are at the first layout level. The pin P31 may be defined by a non-physical layout layer in a layout software. The non-physical layout layer may be defined as the BMD level pin for the signal OUT. The intersection between the pin P31 and the first BMD layout pattern 310y may determine a pin access. The signal OUT may be transmitted from the pin access. The pin access of the pin P31 may be determined based on the type of the standard cell. In some embodiments, the access of the pin P31 may be fixed. The pin access of the pin P31 may not overlap the pin accesses A11 and A12 of the pin P11. The determining of the third pin (e.g. P31) at the second MD layout pattern 250y reduces the number of cell offerings of the circuit layout.

In operation 612, the method 650 includes generating a pin solution for the pin P31. The pin solution may have the information of the position/location of the pin P31. In some embodiments, the position/location of the pin P31 indicates which level (e.g., BMD level) it is designated to. The pin solution may have the information of the output pin of a standard cell. The pin solution may have the information of the pin access of the pin P31.

In some cases, the numbers of the cell offerings for the pin on the higher level (e.g., M0, M1, BM0, BM1) may be increased when designing vertically arranged CFET and could adversely impact the performance of the system 800.

In the present disclosure, the number of the pin accesses for the pins P11, P12, P21, and P31 can be reduced as they are on the PO level or MD level. The combination of the pin solution of the pins P11, P12, P21, and P31 may determine the number of the cell offerings. Since each of the pin solution thereof has relatively small numbers of the pin accesses (some may only have one pin access), the number of the cell offerings can be decreased. In some embodiments, for the circuit layout of the standard cell, there may be one pin solution consisting of the pin solutions of the pins P11, P12, P21, and P31.

The method 650 may further include generating a first interconnection layout pattern (e.g., the interconnection layout pattern 190y) corresponding to fabricating a first interconnection structure (e.g., the interconnection structure 190) of the standard cell, wherein the first interconnection layout pattern 190y is located between the first MD layout pattern 210y and the second MD layout pattern 250y. In some embodiments, the interconnection structure 190 connects the first MD region 210 to the second MD region 250 (FIG. 1).

FIG. 6A is a flow chart of a method 660A of generating a circuit layout of a standard cell in accordance with some embodiments of the present disclosure. The method 660A includes operation 601. The details of operation 601 are illustrated in FIG. 5.

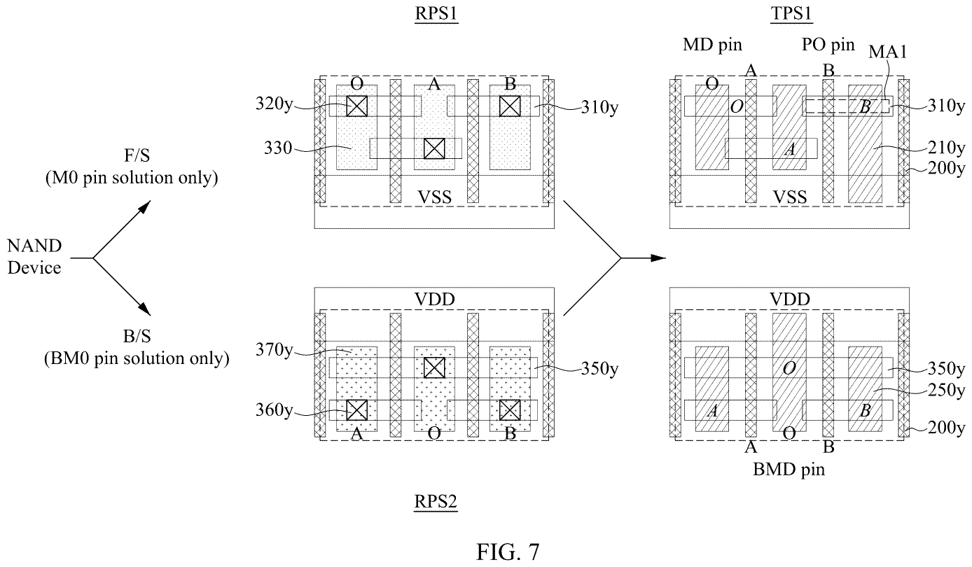

FIG. 7 is a block diagram of generating a circuit layout of a standard cell in accordance with some embodiments of the present disclosure. The block diagram of FIG. 7 corresponds to the operations of the method 660A. FIG. 7 shows the block diagram of generating a circuit layout of a NAND device. The NAND device may include a first input A, a second input B, and an output O. FIG. 7 will be referred to in the explanation of the method 660A.

Referring back to FIG. 6A, in operation 613, the method 660A includes generating a first reference pin solution (e.g., RPS1 in FIG. 7) of the first gate layout pattern (e.g., the gate layout pattern 200y in FIGS. 2A and 2B) to a first frontside conductive feature layout pattern (e.g., the first frontside conductive feature layout pattern 310y in FIG. 2A). The first reference pin solution RPS1 may be only on the first frontside conductive feature layout pattern 310y. The first reference pin solution RPS1 may not be on the first backside conductive feature layout pattern 350y. The first reference pin solution RPS1 corresponds to a first consumption performance.

In some embodiments, in operation 613, the method 660A may include generating a first reference pin solution on the first frontside conductive feature layout pattern 310y for the first MD layout pattern 210y, and the second MD layout pattern 250y.

In operation 615, the method 660A includes generating a target pin solution (e.g., TPS1 in FIG. 7) for the first gate layout pattern (e.g., the gate layout pattern 200y in FIGS. 2A and 2B). The target pin solution TPS1 may be on the first frontside conductive feature layout pattern 310y and/or the first backside conductive feature layout pattern 350y. The target pin solution TPS1 corresponds to a second consumption performance. The target pin solution TPS1 may be constrained by indicating some specified parts of the first frontside conductive feature layout pattern 310y and the first backside conductive feature layout pattern 350y as a reserving region MA1. The indication can be performed by declaring or indicating the specified parts with a non-physical layout layer in a layout software, which does not physically affect a mask/reticle production. The target pin solution TPS1 for signal B of the first gate layout pattern may be only on the specified parts of the first frontside conductive feature layout pattern 310y. In some embodiments, a first gate of the first gate layout pattern 200y may have a reserving region at the first frontside conductive feature layout pattern 310y, while not having any reserving region at the first backside conductive feature layout pattern 350y.

In some embodiments, in operation 613, the method 660A may include generating a target pin solution for the first MD layout pattern 210y and the second MD layout pattern 250y.

In operation 617, the method 660A includes determining whether the second power consumption performance is lower than the first power consumption performance. If yes, the method 660A continues with operation 619, conducting an automatic routing (e.g., the operation 452) based on the target pin solution TPS1. If no, the method 660A goes back to operation 615, generating a further target pin solution for the first gate layout pattern. The further target pin solution differs from the original target pin solution. The operations 615 and 617 will be repeated until the second power consumption is lower than the first power consumption. In other words, the power consumption of the target pin solution TPS1 should be below a threshold value.

The first reference pin solution RPS1 provides a boundary condition to prevent a relatively inadequate power consumption (or speed, area) performance of a target pin solution.

FIG. 6B is a flow chart of a method 660B of generating a circuit layout of a standard cell in accordance with some embodiments of the present disclosure. The method 660B includes operations 601, 613, 615, and 619 of the method 660A of FIG. 6A. The details thereof are illustrated in FIG. 6A. FIG. 7 will be referred to in the explanation of the method 660B.

Referring to FIG. 6B, in operation 614, the method 660B includes generating a second reference pin solution (e.g., RPS2 in FIG. 7) of the first gate layout pattern (e.g., the gate layout pattern 200y in FIGS. 2A and 2B) to a first backside conductive feature layout pattern (e.g., the first backside conductive feature layout pattern 350y in FIG. 2B). The second reference pin solution RPS2 may be only on the first backside conductive feature layout pattern 350y. The second reference pin solution RPS2 may not be on the first frontside conductive feature layout pattern 310y. The second reference pin solution RPS2 corresponds to a third consumption performance.

In some embodiments, in operation 614, the method 660B may include generating a second reference pin solution RPS2 the first MD layout pattern 210y and the second MD layout pattern 250y.

In operation 618, the method 660B includes determining whether the second power consumption performance is lower than the first and third power consumption performances. If yes, the method 660B continues with operation 619, conducting an automatic routing (e.g., the operation 452) based on the target pin solution TPS1. If no, the method 660B goes back to operation 615, generating a further target pin solution for the first gate layout pattern. The further target pin solution differs from the original target pin solution. The operations 614 and 618 will be repeated until the second power consumption is lower than the worsen one of the first and third power consumption. In other words, the power consumption of the target pin solution TPS1 should be below a threshold value.

The first reference pin solution RPS1 and the second reference pin solution RPS2 provide a plurality of boundary conditions to prevent a relatively inadequate power consumption performance of a target pin solution.

FIG. 8 is a flow chart of a method 680 of generating a circuit layout of a standard cell in accordance with some embodiments of the present disclosure. The method 680 includes operation 601, operation 603 and operation 621. The details of operation 601 and operation 603 are already illustrated in FIG. 5.

Referring to FIG. 8, in operation 621, the method 680 includes generating a first pin solution for the first pin at a first frontside conductive feature layout pattern (e.g., the first frontside conductive feature layout pattern 310y) without generating a second pin solution for the first pin at a first backside conductive feature layout pattern (e.g., the first backside conductive feature layout pattern 350y). The standard cell as generated by the method 680 may originate from a frequently used standard cell.

In some embodiment, the operation 621 may further include generating a third pin solution for a second pin at the first backside conductive feature layout pattern (e.g., the first backside conductive feature layout pattern 350y) without generating a fourth pin solution for the second pin at the first frontside conductive feature layout pattern (e.g., the first backside conductive feature layout pattern 310y). The second pin is on the first MD layout pattern 210y.

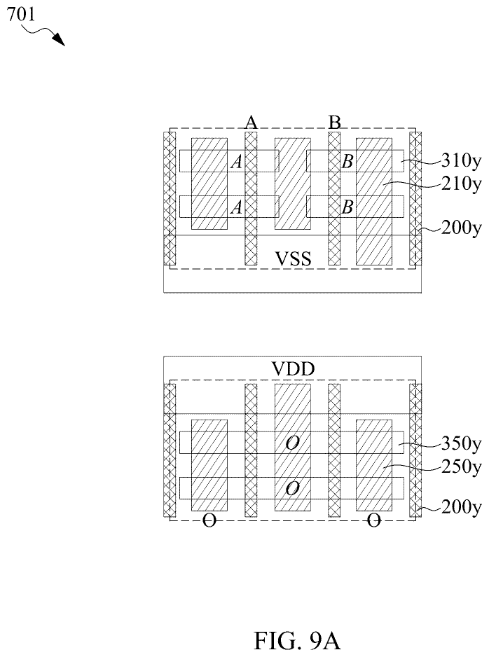

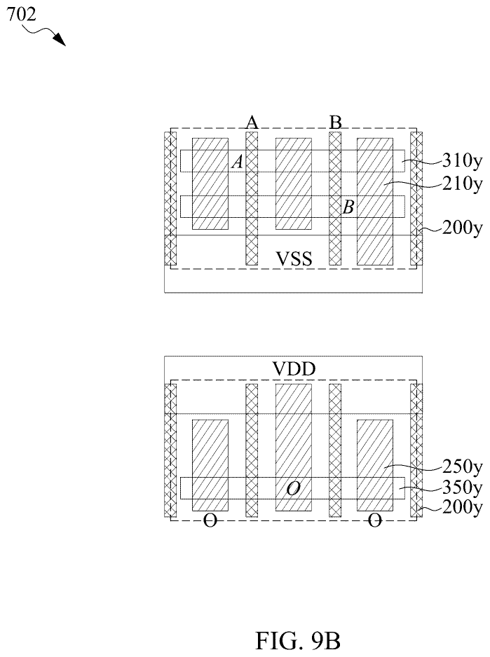

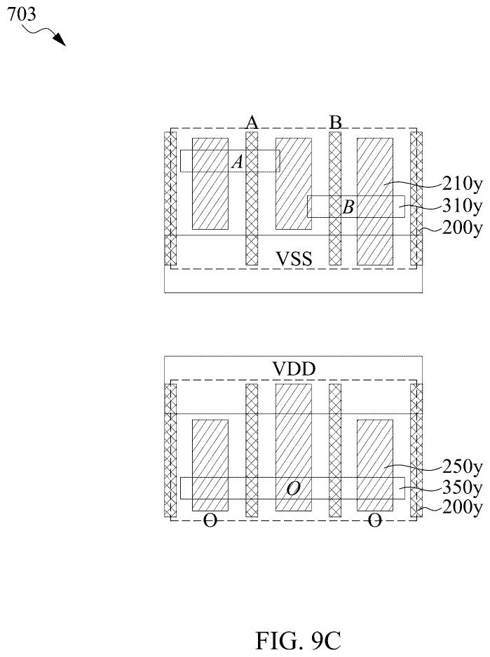

FIG. 9A is a block diagram of a layout of a standard cell (e.g., a NAND device) 701 in accordance with some embodiments of the present disclosure. The standard cell 701 corresponds to the standard cell as generated by the method 680. The standard cell 701 may be a frequently used standard cell. The standard cell 701 may have a pin solution for the first input A at the first frontside conductive feature layout pattern 310y and another pin solution for the second input B at the first frontside conductive feature layout pattern 310y. The pin solution of the standard cell 701 for the first input A and the second input B may not be on the first backside conductive feature layout pattern 350y. The pin solution of the standard cell 701 for the output O may be on the first backside conductive feature layout pattern 350y. The pin solution of the standard cell 701 for the output O may not be on the first frontside conductive feature layout pattern 310y. The pin solution of standard cell 701 may be referenced when generating a target pin solution in operation 615. The target pin solution may be constrained by the pin solution of the standard cell 701. In some embodiments, a plurality of frequently used standard cells may be referenced when generating a target pin solution in operation 615.

FIG. 9B is a block diagram of a layout of a standard cell (e.g., a NAND device) 702 in accordance with some embodiments of the present disclosure. The standard cell 702 corresponds to the standard cell as generated by the method 680. The standard cell 701 is optimized to form the standard cell 702. In order to improve the area performance of the standard cell 701, the frontside conductive feature layout pattern 310y may be modified. As shown in FIG. 9B, a single conductive trace of frontside conductive feature layout pattern 310y is assigned to each of the first input A and the second input B, while a pair of conductive traces in FIG. 9A are assigned to each of the first input A and the second input B. Similarly, a single conductive trace of the backside conductive feature layout pattern 350y is assigned to the output O, while a pair of conductive traces in FIG. 9A are assigned to the output O. The single conductive trace can be directly connected to the pin of a cell of the preceding stage, reducing routing resources.

FIG. 9C is a block diagram of a layout of a standard cell (e.g., a NAND device) 703 in accordance with some embodiments of the present disclosure. The standard cell 703 corresponds to the standard cell as generated by the method 680. The standard cell 701 is optimized to form the standard cell 703. In order to improve the area performance of the standard cell 701, the frontside conductive feature layout pattern 310y may be modified. As shown in FIG. 9C, a single conductive trace of frontside conductive feature layout pattern 310y assigned to the first input A is shorter than that in FIG. 9B. A single conductive trace of frontside conductive feature layout pattern 310y assigned to the second input B is shorter than that in FIG. 9B. The parasitic capacitance in the frontside conductive feature layout pattern 310y can be improved.

In some embodiments, a standard cell including: a gate layout pattern (e.g., 200y) extending in a first direction; a first frontside conductive feature layout pattern (e.g., 310y) overlapping the gate layout pattern; a first backside conductive feature layout pattern (e.g., 350y) overlapping the gate layout pattern. A first input signal (e.g., A) is configured to be transmitted on a first portion of the first frontside conductive feature layout. A second input signal (e.g., B) is configured to be transmitted on a second portion of the first frontside conductive feature layout. The first portion is free from overlapping the second portion in the first direction and a second direction perpendicular to the first direction. The parasitic capacitance in the frontside conductive feature layout pattern 310y can be improved. In some embodiments, an output signal (e.g., O) is configured to be transmitted on the first backside conductive feature layout pattern. The power consumption performance can be improved.

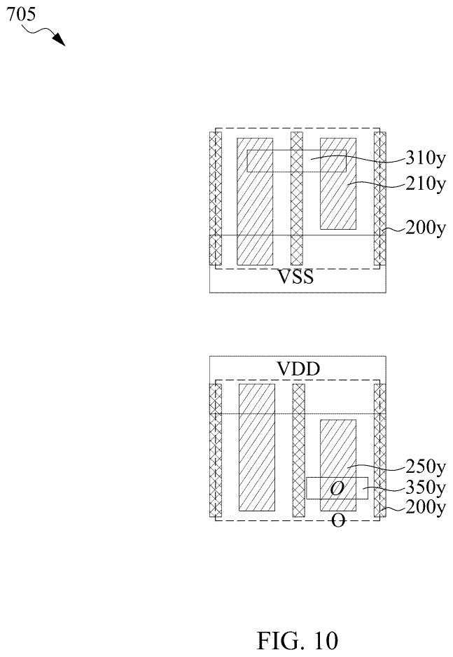

FIG. 10 is a block diagram of a layout of a standard cell (e.g., an inverter) 705 in accordance with some embodiments of the present disclosure. The standard cell 705 may be optimized from an inverter, a pin solution on both of the frontside conductive feature layout pattern 310y and the backside conductive feature layout pattern 350y. The frontside conductive feature layout pattern 310y is only assigned to the input I, while the backside conductive feature layout pattern 350y is only assigned to the output O. The parasitic capacitance in the metal layers can be improved.

FIG. 11 is a diagram illustrating an electronic design automation system 800 in accordance with some embodiments. As shown in FIG. 11, the electronic design automation system 800 includes an electronic design automation (“EDA”) tool 810 having a place and route tool including a chip assembly router 820.

The EDA tool 810 is a special purpose computer configured to retrieve stored program instructions 836 from a computer readable storage medium 830 and 840 and execute the instructions on a general purpose processor 814. Processor 814 may be any central processing unit (“CPU”), microprocessor, micro-controller, or computational device or circuit for executing instructions. The non-transitory computer readable storage medium 830 and 840 may be a flash memory, random access memory (“RAM”), read only memory (“ROM”), or other storage medium. Examples of RAMs include, but are not limited to, static RAM (“SRAM”) and dynamic RAM (“DRAM”). ROMs include, but are not limited to, programmable ROM (“PROM”), electrically programmable ROM (“EPROM”), and electrically erasable programmable ROM (“EEPROM”), to name a few possibilities.

In some embodiments, system 800 includes a display 816 and a user interface or input device 812 such as, for example, a mouse, a touch screen, a microphone, a trackball, a keyboard, or other device through which a user may input design and layout instructions to system 800. In some embodiments, the one or more computer readable storage mediums 830 and 840 may store data input by a user such as a circuit design and cell information 832, which includes a cell library 832a, design rules 834, one or more program files 836, and one or more graphical data system (“GDS”) II files 842.

EDA tool 810 may also include a communication interface 818 allowing software and data to be transferred between EDA tool 810 and external devices. Examples of a communications interface 818 include, but are not limited to, a modem, an Ethernet card, a wireless network card, a Personal Computer Memory Card International Association (“PCMCIA”) slot and card, or the like. Software and data transferred via communications interface 818 may be in the form of signals, which may be electronic, electromagnetic, optical, or the like that are capable of being received by communications interface 818. These signals may be provided to communications interface 818 via a communications path (e.g., a channel), which may be implemented using wire, cable, fiber optics, a telephone line, a cellular link, a radio frequency (“RF”) link and other communication channels. The communications interface 818 may be a wired link and/or a wireless link coupled to a local area network (LAN) or a wide area network (WAN).

Router 820 is capable of receiving an identification of a plurality of cells to be included in a circuit layout, including a list 832 of pairs of cells. The plurality of cells can be connected to each other. In some embodiments, the list 832 can be selected from the cell library 832a. Design rules 834 may be used for a variety of processing technologies. In some embodiments, the design rules 834 configure the router 820 to locate connecting lines and vias on a manufacturing grid. Other embodiments may allow the router to include off-grid connecting lines and/or vias in the layout.

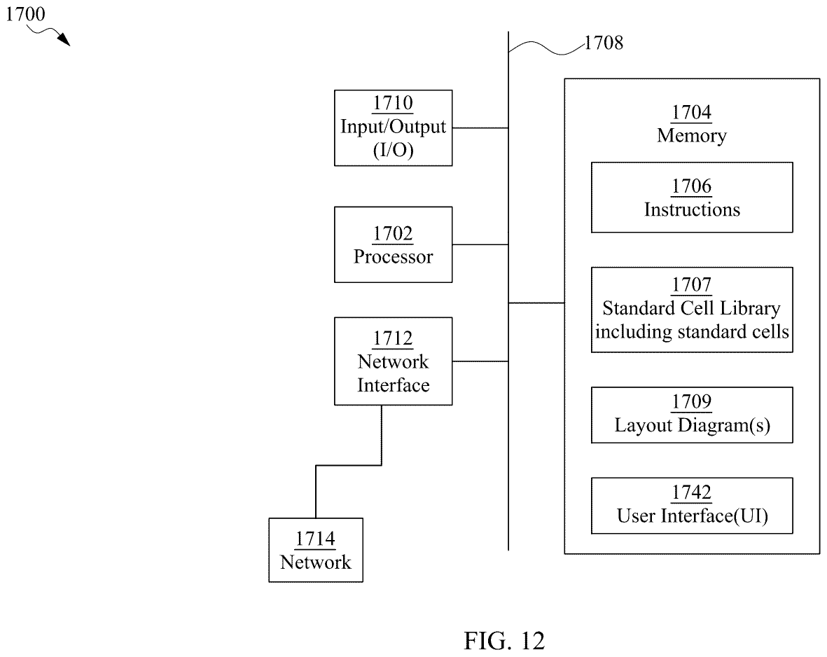

FIG. 12 is a block diagram of IC design system 1700, in accordance with some embodiments. Methods described herein of designing IC layout diagrams in accordance with one or more embodiments are implementable, for example, using IC design system 1700, in accordance with some embodiments. In some embodiments, IC design system 1700 can be an APR system, can include an APR system, or can be a part of an APR system, usable for performing an APR method.

In some embodiments, IC design system 1700 includes a processor 1702 and non-transitory, computer-readable memory 1704. Memory 1704, amongst other things, is encoded with, i.e., stores, computer program code, i.e., a set of executable instructions 1706. Execution of instructions 1706 by the processor 1702 represents (at least in part) an EDA tool which implements a portion or all of a method, e.g., a method of generating an IC layout diagram described above (hereinafter, the noted processes and/or methods).

Processor 1702 is electrically coupled to computer-readable memory 1704 via a bus 1708. Processor 1702 is also electrically coupled to an I/O interface 1710 by bus 1708. Network interface 1712 is also electrically connected to processor 1702 via bus 1708. Network interface 1712 is connected to a network 1714, so that processor 1702 and computer-readable memory 1704 are capable of connecting to external elements via network 1714. Processor 1702 is configured to execute instructions 1706 encoded in computer-readable memory 1704 in order to cause IC design system 1700 to be usable for performing a portion or all of the noted processes and/or methods. In one or more embodiments, processor 1702 is a central processing unit (CPU), a multi-processor, a distributed processing system, an application specific standard cell (ASIC), and/or a suitable processing unit.

In one or more embodiments, memory 1704 is an electronic, magnetic, optical, electromagnetic, infrared, and/or a semiconductor system (or apparatus or device). For example, memory 1704 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 1704 includes a compact disk-read only memory (CD-ROM), a compact disk-read/write (CD-R/W), and/or a digital video disc (DVD).

In one or more embodiments, memory 1704 stores instructions 1706 configured to cause IC design system 1700 (where such execution represents (at least in part) the EDA tool) to be usable for performing a portion or all of the noted processes and/or methods. In one or more embodiments, memory 1704 also stores information which facilitates performing a portion or all of the noted processes and/or methods. In one or more embodiments, memory 1704 includes IC design storage 1707 configured to store one or more IC layout diagrams.

IC design system 1700 includes I/O interface 1710. I/O interface 1710 is coupled to external circuitry. In one or more embodiments, I/O interface 1710 includes a keyboard, keypad, mouse, trackball, trackpad, touchscreen, and/or cursor direction keys for communicating information and commands to processor 1702.

IC design system 1700 also includes network interface 1712 coupled to processor 1702. Network interface 1712 allows IC design system 1700 to communicate with network 1714, to which one or more other computer systems are connected. Network interface 1712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC design systems 1700.

IC design system 1700 is configured to receive information through I/O interface 1710. The information received through I/O interface 1710 includes one or more of instructions, data, design rules, libraries of standard cells, and/or other parameters for processing by processor 1702. The information is transferred to processor 1702 via bus 1708. IC design system 1700 is configured to receive information related to a UI through I/O interface 1710. The information is stored in memory 1704 as user interface (UI) 1742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC design system 1700. In some embodiments, a layout diagram which includes standard cells is generated using a suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

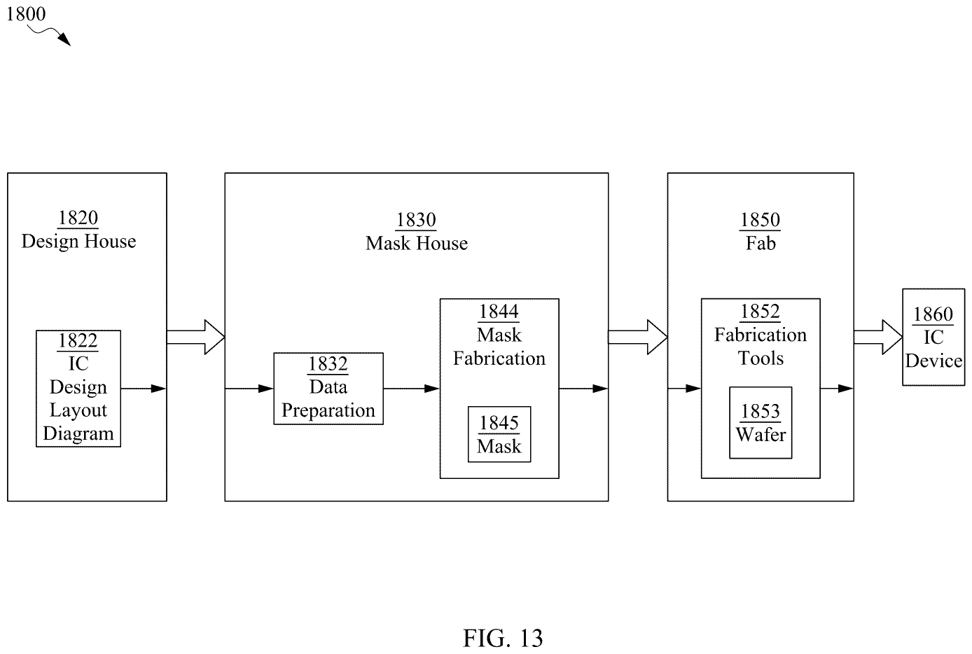

FIG. 13 is a block diagram of IC manufacturing system 1800, and an IC manufacturing flow associated therewith, in accordance with some embodiments. In some embodiments, based on an IC layout diagram, at least one of (A) one or more semiconductor masks or (B) at least one component in a layer of a semiconductor standard cell is fabricated using manufacturing system 1800.

In FIG. 18, IC manufacturing system 1800 includes entities, such as a design house 1820, a mask house 1830, and an IC manufacturer/fabricator (“fab”) 1850, that interact with one another in the design, development, and manufacturing cycles and/or services related to manufacturing an IC device 1860. The entities in system 1800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1820, mask house 1830, and IC fab 1850 is owned by a single larger company. In some embodiments, two or more of design house 1820, mask house 1830, and IC fab 1850 coexist in a common facility and use common resources.

Design house (or design team) 1820 generates an IC design layout diagram 1822. IC design layout diagram 1822 includes various geometrical patterns, e.g., an IC layout diagram discussed above. The geometrical patterns correspond to patterns of metal, oxide, or semiconductor layers that make up the various components of IC device 1860 to be fabricated. The various layers combine to form various IC features. For example, a portion of IC design layout diagram 1822 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1820 implements a proper design procedure to form IC design layout diagram 1822. The design procedure includes one or more of logic design, physical design or place and route. IC design layout diagram 1822 is presented in one or more data files having information of the geometrical patterns. For example, IC design layout diagram 1822 can be expressed in a GDSII file format or DFII file format.

Mask house 1830 includes data preparation 1832 and mask fabrication 1844. Mask house 1830 uses IC design layout diagram 1822 to manufacture one or more masks 1845 to be used for fabricating the various layers of IC device 1860 according to IC design layout diagram 1822. Mask house 1830 performs mask data preparation 1832, where IC design layout diagram 1822 is translated into a representative data file (RDF). Mask data preparation 1832 provides the RDF to mask fabrication 1844. Mask fabrication 1844 includes a mask writer. A mask writer converts the RDF to an image on a substrate, such as mask (reticle) 1845 or a semiconductor wafer 1853. The design layout diagram 1822 is manipulated by mask data preparation 1832 to comply with particular characteristics of the mask writer and/or requirements of IC fab 1850. In FIG. 13, mask data preparation 1832 and mask fabrication 1844 are illustrated as separate elements. In some embodiments, mask data preparation 1832 and mask fabrication 1844 can be collectively referred to as mask data preparation.

In some embodiments, mask data preparation 1832 includes optical proximity correction (OPC) which uses lithography enhancement techniques to compensate for image errors, such as those that can arise from diffraction, interference, other process effects and the like. OPC adjusts IC design layout diagram 1822. In some embodiments, mask data preparation 1832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1832 includes a mask rule checker (MRC) that checks the IC design layout diagram 1822 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1822 to compensate for limitations during mask fabrication 1844, which may undo part of the modifications performed by OPC in order to meet mask creation rules.

In some embodiments, mask data preparation 1832 includes lithography process checking (LPC) that simulates processing that will be implemented by IC fab 1850 to fabricate IC device 1860. LPC simulates this processing based on IC design layout diagram 1822 to create a simulated manufactured device, such as IC device 1860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1822.

It should be understood that the description of mask data preparation 1832 has been simplified for the purposes of clarity. In some embodiments, data preparation 1832 includes additional features such as a logic operation (LOP) to modify the IC design layout diagram 1822 according to manufacturing rules. Additionally, the processes applied to IC design layout diagram 1822 during data preparation 1832 may be executed in a variety of different orders.

After mask data preparation 1832 and during mask fabrication 1844, a mask 1845 or a group of masks 1845 are fabricated based on the modified IC design layout diagram 1822. In some embodiments, mask fabrication 1844 includes performing one or more lithographic exposures based on IC design layout diagram 1822. In some embodiments, an electron-beam (e-beam) or a mechanism of multiple e-beams is used to form a pattern on a mask (photomask or reticle) 1845 based on the modified IC design layout diagram 1822. Mask 1845 can be formed in various technologies. In some embodiments, mask 1845 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 1845 includes a transparent substrate (e.g., fused quartz) and an opaque material (e.g., chromium) coated in the opaque regions of the binary mask. In another example, mask 1845 is formed using a phase shift technology. In a phase shift mask (PSM) version of mask 1845, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1844 is used in a variety of processes. For example, such a mask(s) is used in an ion implantation process to form various doped regions in semiconductor wafer 1853, in an etching process to form various etching regions in semiconductor wafer 1853, and/or in other suitable processes.

IC fab 1850 is an IC fabrication business that includes one or more manufacturing facilities for the fabrication of a variety of different IC products. In some embodiments, IC Fab 1850 is a semiconductor foundry. For example, there may be a manufacturing facility for the front-end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1850 includes wafer fabrication tools 1852 configured to execute various manufacturing operations on semiconductor wafer 1853 such that IC device 1860 is fabricated in accordance with the mask(s), e.g., mask 1845. In various embodiments, fabrication tools 1852 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1850 uses mask(s) 1845 fabricated by mask house 1830 to fabricate IC device 1860. Thus, IC fab 1850 at least indirectly uses IC design layout diagram 1822 to fabricate IC device 1860. In some embodiments, semiconductor wafer 1853 is fabricated by IC fab 1850 using mask(s) 1845 to form IC device 1860. In some embodiments, the IC fabrication includes performing one or more lithographic exposures based at least indirectly on IC design layout diagram 1822. Semiconductor wafer 1853 includes a silicon substrate or other proper substrate having material layers formed thereon. Semiconductor wafer 1853 further includes one or more of various doped regions, dielectric features, multilevel interconnects, and the like (formed at subsequent manufacturing steps).

The present disclosure provides a method of forming a semiconductor device, comprising: generating, by a processor, a circuit layout of the standard cell, wherein the generating of the circuit layout comprises: generating a first gate layout pattern corresponding to fabricating a first gate structure of the standard cell; determining a first pin at the first gate layout pattern; and determining a first pin solution based on the first pin; and manufacturing the standard cell based on the circuit layout, the standard cell having the first gate structure.

The present disclosure provides a method of forming a semiconductor device, comprising: generating, by a processor, a circuit layout of the standard cell, wherein the generating of the circuit layout comprises: generating a first gate layout pattern corresponding to fabricating a first gate structure of the standard cell; generating a first reference pin solution of the first gate layout pattern to a first frontside conductive feature layout pattern corresponding to fabricating a first frontside conductive structure of the standard cell, the first reference pin solution corresponding to a first power consumption performance; generating a target pin solution for the first gate layout pattern, the target pin solution corresponding to a second power consumption performance, determining whether the second power consumption performance is lower than the first power consumption performance; and manufacturing the standard cell based on the circuit layout, the standard cell having the first gate structure and the first frontside conductive structure.

The present disclosure provides a semiconductor device including: a gate layout pattern extending in a first direction; a first frontside conductive feature layout pattern overlapping the gate layout pattern; a first backside conductive feature layout pattern overlapping the gate layout pattern, wherein a first input signal is configured to be transmitted on a first portion of the first frontside conductive feature layout, and a second input signal is configured to be transmitted on a second portion of the first frontside conductive feature layout, and wherein the first portion is free from overlapping the second portion in the first direction and a second direction perpendicular to the first direction.

The methods and features of the present disclosure have been sufficiently described by examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein may be utilized according to the present disclosure.

Accordingly, the appended claims are intended to include within their scope, processes, machines, manufacture, compositions of matter, means, methods or steps. In addition, each claim constitutes a separate embodiment, and the combination of various claims and embodiments are within the scope of the present disclosure.

What is claimed is:

1. A method of forming a semiconductor device, comprising:
generating, by a processor, a circuit layout of the standard cell, wherein the generating of the circuit layout comprises:
generating a first gate layout pattern corresponding to fabricating a first gate structure of the standard cell;
determining a first pin at the first gate layout pattern; and
generating a first pin solution based on the first pin; and
manufacturing the standard cell based on the circuit layout, the standard cell having the first gate structure.

2. The method of claim 1, wherein the generating of the circuit layout comprises:
generating a first metal over a diffusion (MD) layout pattern corresponding to fabricating a first MD region of the standard cell;
determining a second pin at the first MD layout pattern; and
generating a second pin solution based on the second pin.

3. The method of claim 2, wherein the generating of the circuit layout comprises:
generating a second MD layout pattern corresponding to fabricating a second MD region of the standard cell, wherein the second MD layout pattern is located below the first MD layout pattern;
determining a third pin at the second MD layout pattern; and
generating a third pin solution based on the third pin.

4. The method of claim 2, wherein the first gate layout pattern and the first MD layout pattern collectively determine a set of n-type transistors.

5. The method of claim 3, wherein the first gate layout pattern and the second MD layout pattern collectively determine a set of p-type transistors.

6. The method of claim 1, wherein the first gate structure is a part of a vertically arranged complementary FET (CFET).

7. The method of claim 3, wherein the generating of the circuit layout comprises:
generating an interconnection layout pattern corresponding to fabricating an interconnection structure of the standard cell, wherein the interconnection layout pattern is located between the first MD layout pattern and the second MD layout pattern.

8. The method of claim 7, wherein the interconnection structure connects the first MD region to the second MD region.

9. The method of claim 3, wherein the first pin, the second pin, and the third pin are at a first layout level.

10. The method of claim 1, wherein the determining of the first pin at the first gate layout pattern reduces the number of cell offerings of the circuit layout.

11. A method of forming a semiconductor device, comprising:
generating, by a processor, a circuit layout of the standard cell, wherein the generating of the circuit layout comprises:
generating a first gate layout pattern corresponding to fabricating a first gate structure of the standard cell;
generating a first reference pin solution of the first gate layout pattern to a first frontside conductive feature layout pattern corresponding to fabricating a first frontside conductive structure of the standard cell, the first reference pin solution corresponding to a first power consumption performance;
generating a target pin solution for the first gate layout pattern, the target pin solution corresponding to a second power consumption performance;
determining whether the second power consumption performance is lower than the first power consumption performance; and
manufacturing the standard cell based on the circuit layout, the standard cell having the first gate structure.

12. The method of claim 11, wherein the generating of the circuit layout comprises:
generating a second reference pin solution for the first gate layout pattern at a first backside conductive feature layout pattern corresponding to fabricating a first backside conductive layer of the standard cell, the second reference pin solution corresponding to a third power consumption performance.

13. The method of claim 12, wherein the generating of the circuit layout comprises:
determining whether the second power consumption performance is lower than the first and third power consumption performances.

14. The method of claim 12, wherein the generating of the target pin solution comprises:
constraining the target pin solution by a pin solution of a frequently used standard cell.

15. The method of claim 11, wherein the generating of the circuit layout comprises:
generating a further target pin solution if the second power consumption performance is higher than the first power consumption performance.

16. The method of claim 11, wherein the generating of the circuit layout comprises:
generating a first metal over a diffusion (MD) layout pattern corresponding to fabricating a first MD region of the standard cell; and
generating a third reference pin solution of the first MD layout pattern to the first frontside conductive feature layout pattern, wherein the third reference pin solution corresponds to the first power consumption performance.

17. The method of claim 16, wherein the generating of the circuit layout comprises:
generating a second MD layout pattern corresponding to fabricating a second MD region of the standard cell; and
generating a fourth reference pin solution of the second MD layout pattern to the first frontside conductive feature layout pattern, wherein the fourth reference pin solution corresponds to the first power consumption performance.

18. The method of claim 11, wherein the generating of the circuit layout comprises a plurality of layout patterns of a vertically arranged CFET.

19. A semiconductor device, comprising:
a gate layout pattern extending in a first direction;
a first frontside conductive feature layout pattern overlapping the gate layout pattern; and
a first backside conductive feature layout pattern overlapping the gate layout pattern,
wherein a first input signal is configured to be transmitted on a first portion of the first frontside conductive feature layout, and a second input signal is configured to be transmitted on a second portion of the first frontside conductive feature layout, and
wherein the first portion is free from overlapping the second portion in the first direction and a second direction perpendicular to the first direction.

20. The semiconductor device of claim 19, wherein an output signal is configured to be transmitted on the first backside conductive feature layout pattern.
